(19) United States
(12) Patent Application Publication
(10) Pub. No.: US 2026/0040794 A1
(43) Pub. Date: Feb. 5, 2026

(54) DISPLAY MODULE INCLUDING AN ADHESIVE, ELECTRONIC DEVICE INCLUDING THE SAME, AND METHOD FOR MANUFACTURING THE DISPLAY MODULE

(71) Applicant: SAMSUNG DISPLAY CO., LTD., Yongin-si (KR)

(72) Inventors: Intae SON, Yongin-si (KR); WON-SEOK KIM, Yongin-si (KR); JUEYOUN PARK, Yongin-si (KR); KANG-WOO LEE, Yongin-si (KR); Dasong LEE, Yongin-si (KR); HYUNJUNG LEE, Yongin-si (KR); Jinyeong HEO, Yongin-si (KR)

(21) Appl. No.: 19/246,948

(22) Filed: Jun. 24, 2025

(30) Foreign Application Priority Data
Aug. 1, 2024 (KR) 10-2024-0102722

(51) Int. Cl. H10K 59/80; H10K 102/00

(52) U.S. Cl. CPC H10K 59/8722; H10K 59/873; H10K 2102/311

(57) ABSTRACT

Provided is a display module. The display module includes a display unit comprising a flat part and a bent part that extends from the flat part, a window disposed on the display unit, and an adhesive layer disposed between the display unit and the window. The adhesive layer comprises a first adhesive material with a first degree of adhesiveness that is dependent upon exposure to a first light.

### CROSS-REFERENCE TO RELATED APPLICATIONS

This U.S. non-provisional patent application claims priority under 35 U.S.C. § 119 to Korean Patent Application No. 10-2024-0102722, filed on Aug. 1, 2024 in the Korean Intellectual Property Office, the entire contents of which are herein incorporated by reference in their entirety.

### TECHNICAL FIELD

The present disclosure relates to a display module and, more specifically to a display module including an adhesive, an electronic device including the same, and a method for manufacturing the display module.

### DISCUSSION OF THE RELATED ART

Multimedia devices, such as televisions, mobile phones, tablet computers, navigation systems, portable game consoles, etc. are electronic devices that include a display module image display. As the display module technology advances, various types of display modules have been developed. For example, the display module may display an image on a curved display surface.

The display module may be manufactured by laminating a display panel, which includes a display panel and a window. The display module with a curved surface may be formed by bonding the display panel and the window, each of which has the curved surface, together. However, during the lamination process, portions having the cured surfaces of the display panel and the window might not be completely bonded, or may be damaged due to having a relatively low durability.

### SUMMARY

An embodiment of the inventive concept provides a display module including a display panel comprising a flat part and a bent part that extends from the flat part, a window disposed on the display panel, and an adhesive disposed between the display panel and the window. The adhesive comprises a first adhesive material with a first degree of adhesiveness that is dependent upon exposure to a first light.

In an embodiment of the inventive concept, an electronic device includes a processor, a memory having stored application programs for execution by the processor, a display device, and a user interface configured to sense user input via touch or cursor a cursor selection of an icon presented on the display panel. The processor is caused to execute one or more stored application programs upon receipt of the user input. The display device includes a display panel comprising a flat part and a bent part that extends from the flat part, a window disposed on the display panel, an adhesive disposed between the display panel and the window, and a housing coupled to the window and accommodating the display panel. The adhesive comprises a first adhesive material having a first degree of adhesiveness that is dependent upon exposure to a first light.

In an embodiment of the inventive concept, a method for manufacturing a display module includes providing a pressing pad comprising a curved pressing surface, disposing a preliminary display module comprising a display panel and a first preliminary adhesive, which is disposed on the display panel, on the pressing pad, exposing the preliminary display module to a first light to form a second preliminary adhesive, disposing a window on the second preliminary adhesive, attaching the display panel to the window through the second preliminary adhesive; and exposing the window to a second light to form an adhesive. A first adhesive strength of the second preliminary adhesive is less than a second adhesive strength of the adhesive.

### BRIEF DESCRIPTION OF THE FIGURES

The accompanying drawings are included to provide a further understanding of the inventive concept, and are incorporated in and constitute a part of this specification. The drawings illustrate embodiments of the present inventive concept and, together with the description, serve to explain principles of the present inventive concept. In the drawings:

FIG. 1 is a perspective view of an electronic device according to an embodiment of the present inventive concept;

FIG. 2 is a block diagram of the electronic device according to an embodiment of the present inventive concept;

FIG. 3 is an exploded perspective view of the electronic device of FIG. 1;

FIG. 4 is a cross-sectional view of a display panel according to an embodiment of the present inventive concept;

FIG. 5 is a cross-sectional view of a display module according to an embodiment of the present inventive concept;

FIG. 6 is a flowchart illustrating a method for manufacturing a display module according to an embodiment of the present inventive concept; and

FIGS. 7A, 7B, 7C, 7D, 7E, and 7F are cross-sectional views illustrating some of steps in the method for manufacturing the display module according to an embodiment of the present inventive concept.

### DETAILED DESCRIPTION

Since the present disclosure may have diverse modified embodiments, specific embodiments are illustrated in the drawings and are described in the detailed description of the present inventive concept. However, this does not necessarily limit the present disclosure within specific embodiments and it should be understood that the present disclosure covers the modifications, equivalents, and replacements within the idea and technical scope of the present disclosure.

In this specification, it will also be understood that when one component (or region, layer, portion) is referred to as being ‘on’, ‘connected to’, or ‘coupled to’ another component, it can be directly disposed/connected/coupled on/to the one component, or an intervening third component may also be present.

Like reference may numerals refer to like elements throughout the specification and the drawings. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like.

It will be understood that although the terms such as ‘first’ and ‘second’ are used herein to describe various elements, these elements should not necessarily be limited by these terms. The terms are used to distinguish one component from other components. For example, a first element referred to as a first element in an embodiment can be referred to as a second element in another embodiment without departing from the scope of the appended claims. The terms of a singular form may include plural forms unless referred to the contrary.

Also, “under”, “below”, “above”, “upper”, and the like are used for explaining relation association of components illustrated in the drawings. The terms may be a relative concept and described based on directions expressed in the drawings.

The meaning of ‘include’ or ‘comprise’ specifies a property, a fixed number, a step, an operation, an element, a component or a combination thereof, but does not exclude other properties, fixed numbers, steps, operations, elements, components or combinations thereof. According to embodiments of the present inventive concept, a display module may include a display panel including bent portions, a window arranged on the display panel, and an adhesive disposed between the display panel and the window.

A flat part of the display panel and a main transmission surface of the window are flat, but the bent parts of the display panel and the corresponding side transmission surfaces of the window are curved. While the flat part may be easily bonded, the bent parts and the side transmission surfaces may be difficult to bond effectively.

In traditional methods, uneven adhesive distribution of the adhesive may form blobs or concentrate in specific spots. Moreover, bubbles may form between the display panel and the window, especially in curved areas.

According to embodiments of the present inventive concept, the display panel is attached to the window using an adhesive that is in a softened state when first applied. The soft state allows the adhesive to spread more evenly across the surfaces, including bent parts and the side transmission surfaces. Because the adhesive is softened when applied, it may cover curved areas and ensure that it bonds effectively.

By using the softened adhesive, it may help prevent bubbles from forming, improving the overall bonding reliability.

According to embodiments of the present inventive concept, the adhesive may exhibit adhesive reversibility. For example, the adhesive is in a softened state when first applied and then cured under visible light. Once cured, the adhesive may form a strong bond between the display panel and the window, ensuring a high-strength attachment.

Hereinafter, a display module and a method for attaching the display module to the window according to an embodiment of the present inventive concept will be described with reference to the drawings.

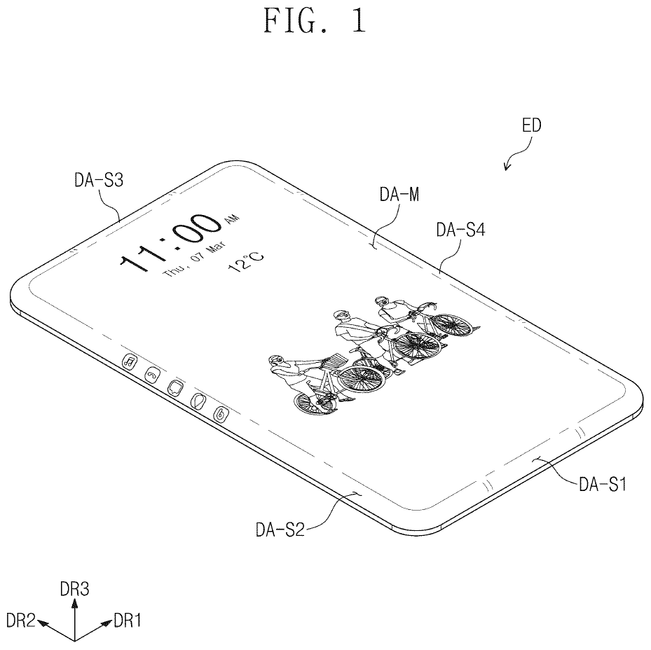

FIG. 1 is a perspective view of an electronic device ED according to an embodiment of the inventive concept.

Referring to FIG. 1, the electronic device ED may be a device that is activated by an electrical signal to display an image. For example, the electronic device ED may include various types of devices. The electronic device ED may include, for example, at least one of a portable communication device (e.g., a smart phone), a computer device, a portable multimedia device, a portable medical device, a digital camera, a wearable device, or a home appliance device. However, embodiments of the electronic device ED are illustrative and are not necessarily limited to any one embodiment without departing from the spirit of the inventive concept. In this embodiment of the present inventive concept, a mobile phone is illustrated as an example of the electronic device ED.

A display area may be defined on the electronic device ED. The electronic device ED may display an image through the display area and receive an external input. The display area of the electronic device ED may include a main display area DA-M and first to fourth sub-display areas DA-S1, DA-S2, DA-D3, and DA-S4.

The main display area DA-M may be substantially parallel to a plane defined by the first direction DR1 and the second direction DR2. However, this embodiment is not necessarily limited thereto, and the main display area DA-M may have a shape that is concave or convexly curved with respect to the plane defined by the first direction DR1 and the second direction DR2.

The main display area DA-M may display an image in a third direction DR3 intersecting each of the first direction DR1 and the second direction DR2. A front surface (or top surface) and a rear surface (or bottom surface) of each member constituting the electronic device ED may be disposed opposite from each other in the third direction DR3, and the third direction DR3 may be defined as a thickness direction of the electronic device ED.

In this specification, “on a plane” or “in a plan view” may be defined in a state when viewed in the third direction DR3. In this specification, “in a cross-section” may be defined in a state when viewed in the first direction DR1 or the second direction DR2. The directions indicated as the first to third directions DR1, DR2, and DR3 may be a relative concept and thus changed into different directions.

The main display area DA-M may have a rectangular shape having a pair of short sides extending primarily in the first direction DRI and a pair of long sides extending primarily in the second direction DR2. However, this embodiment is not necessarily limited thereto, and the main display area DA-M may have various shapes such as a circle or polygon on the plane.

Each of the first to fourth sub-display areas DA-S1, DA-S2, DA-D3, and DA-S4 may be bent from the main display area DA-M. Each of the first to fourth sub-display areas DA-S1, DA-S2, DA-D3, and DA-S4 may be bent at a curvature and may include a curved surface. The curvatures of the first to fourth sub-display areas DA-S1, DA-S2, DA-D3, and DA-S4 may be the same, but is not necessarily limited thereto, and at least some of the first to fourth sub-display areas DA-S1, DA-S2, DA-D3, and DA-S4 may be different from each other.

The main display area DA-M and the first to fourth sub-display areas DA-S1, DA-S2, DA-D3, and DA-S4 may be adjacent to each other to implement a continuous display area. The first to fourth sub-display areas DA-S1, DA-S2, DA-D3, and DA-S4 may be connected to each other to surround the main display area DA-M. Each of the first sub-display area DA-S1 and the third sub-display area DA-S3 may extend from the short sides of the main display area DA-M parallel to the first direction DR1, and each of the second sub-display area DA-S2 and the fourth sub-display area DA-S4 may extend from the long sides of the main display area DA-M parallel to the second direction DR2.

FIG. 1 illustrates four sub-display areas DA-S1, DA-S2, DA-S3, and DA-S4 extending from four sides of the main display area DA-M, but is not necessarily limited thereto, and the display area of the electronic device ED may include a bent sub-display area extending from at least one of the four sides of the main display area DA-M. For example, the electronic device ED according to an embodiment of the present inventive concept may include only some of the four sub-display areas DA-S1, DA-S2, DA-S3, and DA-S4.

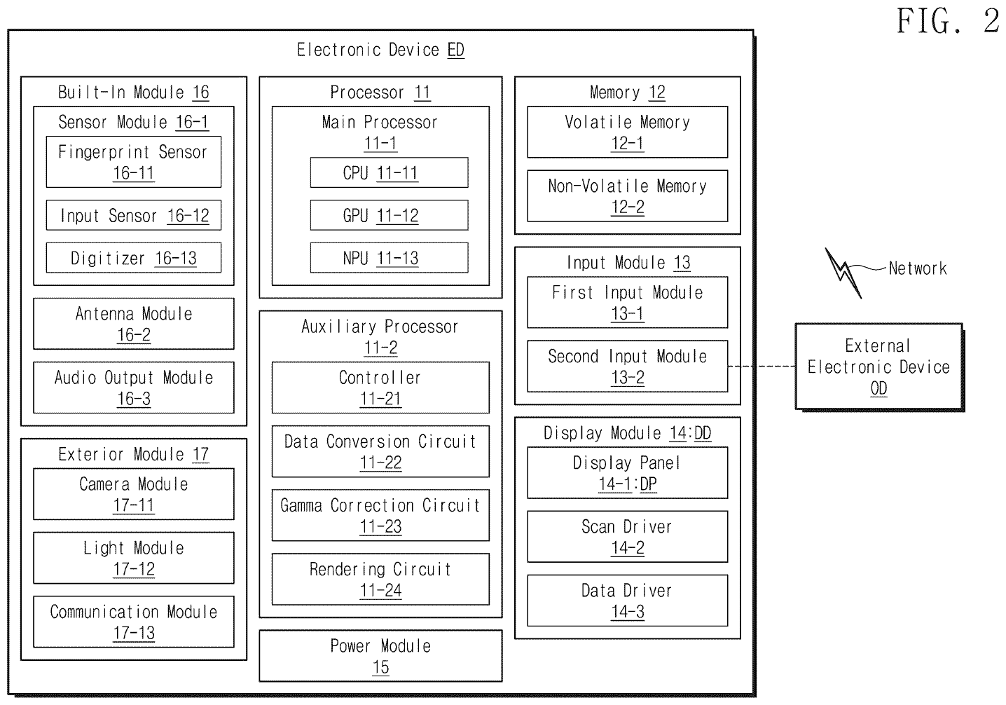

FIG. 2 is a block diagram of the electronic device ED according to an embodiment of the present inventive concept.

The electronic device ED may output various information through a display module 14 within an operating system. When a processor 11 executes an application stored in a memory 12, the display module 14 may provide application information to the user through a display panel 14-1. The display module 14 illustrated in FIG. 2 may refer to a display module DM described later, and the display panel 14-1 may refer to a display panel DP described later.

The processor 11 may acquire an external input through an input module 13 or a sensor module 16-1 to execute an application corresponding to the external input. For example, when the user selects a camera icon displayed on the display panel 14-1, the processor 11 may acquire a user input through an input sensor 16-12 to activate a camera module 17-1. The processor 11 may transmit image data corresponding to a photographed image acquired through the camera module 17-1 to the display module 14. The display module 14 may display an image corresponding to the photographed image through the display panel 14-1.

As an example of the present inventive concept, when personal information authentication is performed in the display module 14, a fingerprint sensor 16-11 may acquire the input fingerprint information as input data. The processor 11 may compare the input data acquired through the fingerprint sensor 16-11 with authentication data stored in the memory 12 to execute an application based on the comparison result. The display module 14 may display information executed according to logic of the application through the display panel 14-1.

As an example of the present inventive concept, when a music streaming icon displayed on the display module 14 is selected, the processor 11 may acquire a user input through the input sensor 16-12 to activate a music streaming application stored in the memory 12. When a music execution command is input in the music streaming application, the processor 11 may activate an audio output module 16-3 to provide audio information corresponding to the music execution command to the user.

Hereinabove, the operation of the electronic device ED is briefly described. The configuration of the electronic device ED will be described in detail below. Some of the components of the electronic device ED described below may be integrated and provided as one component, or one component may be provided by being separated into two or more components.

Referring to FIG. 2, the electronic device ED may communicate with an external electronic device OD through a network (e.g., a short-range wireless communication network or a long-range wireless communication network). According to an embodiment, the electronic device ED may include a processor 11, a memory 12, an input module 13, a display module 14, a power module 15, a built-in module 16, and an exterior module 17. According to an embodiment of the present inventive concept, the electronic device ED may omit at least one of the above-described components or may add one or more other components. In an embodiment of the present inventive concept, some of the components described above (e.g., the sensor module 16-1, the antenna module 16-2, or the audio output module 16-3) may be integrated into another component (e.g., the display module 14).

The processor 11 may execute software to control at least one other component (e.g., a hardware or software component) of the electronic device ED connected to the processor 11 and perform various data processing or operations. According to an embodiment of the present inventive concept, as at least a portion of data processing or calculation, the processor 11 may store a command or data received from another component (e.g., the input module 13, the sensor module 16-1, or a communication module 17-3) in a volatile memory 12-1, process the command or data stored in the volatile memory 12-1, and store the resulting data in a non-volatile memory 12-2.

The processor 11 may include a main processor 11-1 and an auxiliary processor 11-2. The main processor 11-1 may include one or more of a central processing unit (CPU) 11-11 or an application processor (AP). The main processor 11-1 may further include one or more of a graphic processing unit (GPU) 11-12, a communication processor (CP), and an image signal processor (ISP). The main processor 11-1 may further include a neural processing unit (NPU) 11-13. The neural network processing unit may be a processor specialized in processing an artificial intelligence model, and the artificial intelligence model may be created through machine learning. The artificial intelligence model may include multiple artificial neural network layers. The artificial neural network may be one of a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, or a combination of two or more thereof, but is not necessarily limited to the examples described above. The artificial intelligence model may additionally or alternatively include a software structure in addition to the hardware structure. At least two of the processing units and the processors, which are described above, may be implemented as a single integrated configuration (e.g., a single chip), or each of the processing units and the processors may be implemented as an independent configuration (e.g., multiple chips).

The auxiliary processor 11-2 may include a controller 11-21. The controller 11-21 may include an interface conversion circuit and a timing control circuit. The controller 11-21 may receive a video signal from the main processor 11-1, convert data format of the video signal to match the interface specifications with the display module 14, and output video data. The controller 11-21 may output various control signals that are necessary for driving the display module 14.

The auxiliary processor 11-2 may further include a data conversion circuit 11-22, a gamma correction circuit 11-23, a rendering circuit 11-24, etc. The data conversion circuit 11-22 may receive image data from the controller 11-21 to compensate for the image data so that the image is displayed at desired brightness or convert the image date so as to reduce power consumption or compensate for an afterimage. The gamma correction circuit 11-23 may convert image data or a gamma reference voltage, etc. so that the image displayed on the electronic device ED has desired gamma characteristics. The rendering circuit 11-24 may receive the image data from the controller 11-21 and may render the image data in consideration of the arrangement of the pixels of the display panel 14-1 applied to the electronic device ED. At least one of the data conversion circuit 11-22, the gamma correction circuit 11-23, or the rendering circuit 11-24 may be integrated into another component (e.g., the main processor 11-1 or the controller 11-21). At least one of the data conversion circuit 11-22, the gamma correction circuit 11-23, or the rendering circuit 11-24 may be integrated into a data driver 143 described below.

The memory 12 may store various data used by at least one component of the electronic device ED (e.g., the processor 11 or the sensor module 16-1) and input data or output data for commands related thereto. The memory 12 may include at least one of the volatile memory 12-1 or the non-volatile memory 12-2.

The input module 13 may receive commands or data to be used for the components of the electronic device ED (e.g., the processor 11, the sensor module 16-1, or the audio output module 16-3) from outside the electronic device ED (e.g., the user or the external electronic device OD).

The input module 13 may include a first input module 13-1 into which a command or data is input from a user and a second input module 13-2 into which a command or data is input from an external electronic device OD. The first input module 13-1 may include a microphone, a mouse, a keyboard, a key (e.g., a button), or a pen/stylus (e.g., a passive pen or an active pen). The second input module 13-2 may support a designated protocol that may be connected with wire or wirelessly to the external electronic device OD. According to an embodiment of the present inventive concept, the second input module 13-2 may include a high definition multimedia interface (HDMI), a universal serial bus (USB) interface, an SD card interface, or an audio interface. The second input module 13-2 may include a connector that may be physically connected to the external electronic device OD, for example, the HDMI connector, the USB connector, the SD card connector, or the audio connector (e.g., a headphone connector).

The display module 14 may provide information visually to the user. The display module 14 may include a display panel 14-1, a scan driver 14-2, and a data driver 143. The display module 14 may further include a window, a chassis, and a bracket to protect the display panel 14-1.

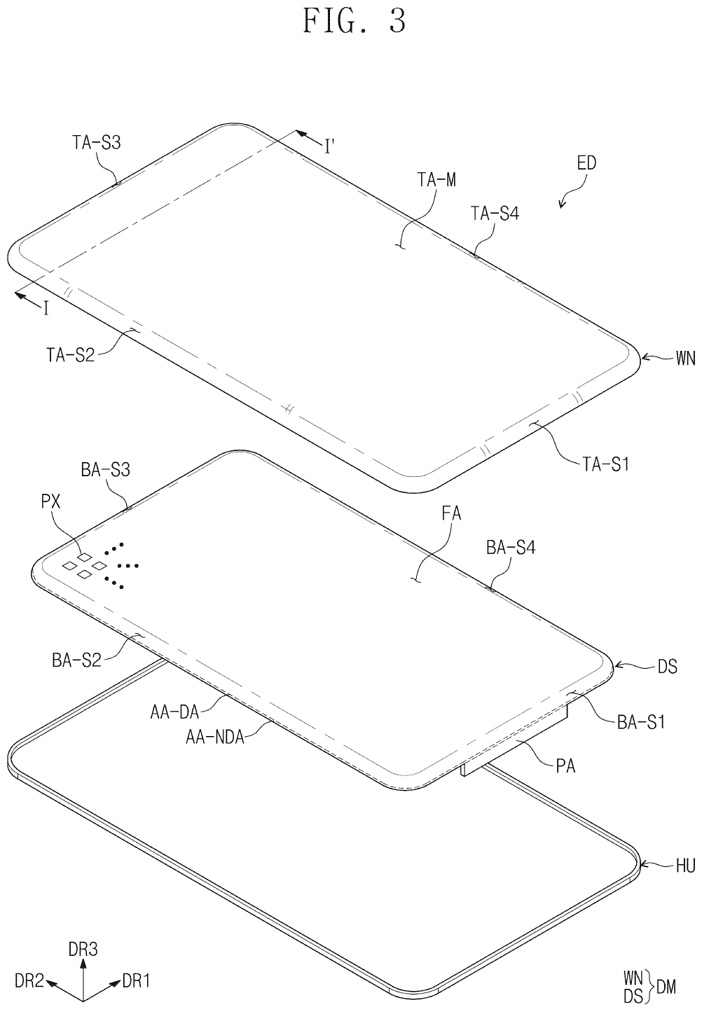

The display panel 14-1 may include a liquid crystal display (LCD) panel, an organic light emitting diode (OLED) display panel, or an inorganic light emitting display panel, and the type of the display panel 14-1 is not necessarily particularly limited to what is described herein. The display panel 14-1 may be of a rigid type or a flexible type capable of being rolled or folded. The display module 14 may further include a supporter, a bracket, or a heat dissipation structure that supports the display panel 14-1. A specific description of the display panel 14-1 may be provided below in FIG. 3.

The scan driver 14-2 may be mounted on the display panel 14-1 as a driving chip. In addition, the scan driver 14-2 may be integrated into the display panel 14-1. For example, the scan driver 14-2 may include an amorphous silicon TFT gate (ASG) driver circuit, a low temperature polycrystalline silicon (LTPS) TFT gate driver circuit, or an oxide semiconductor TFT gate (OSG) driver circuit), which is built into the display panel 14-1. The scan driver 14-2 may receive a control signal from the controller 11-21 and output scan signals to the display panel 14-1 in response to the control signal.

The display panel 14-1 may further include a light emitting driver. The light emitting driver may output an emission control signal to the display panel 14-1 in response to the control signal received from the controller 11-21. The light emitting driver may be provided to be distinguished from the scan driver 14-2 or may be integrated into the scan driver 14-2.

The data driver 143 may receive the control signal from the controller 11-21 and convert image data into an analog voltage (e.g., data voltage) in response to the control signal, and then output the data voltage to the display panel 14-1.

The data driver 143 may be integrated into another component (e.g., the controller 11-21). A function of each of the interface conversion circuit and the timing control circuit of the above-described controller 11-21 may be integrated into the data driver 143.

The display module 14 may further include a light emitting driver and a voltage generation circuit, etc. The voltage generation circuit may output various voltages required to drive the display panel 14-1.

The power module 15 may supply power to the components of the electronic device ED. The power module 15 may include a battery that charges the power voltage. The battery may include a non-rechargeable primary battery, a rechargeable secondary battery, or a fuel cell. The power module 15 may include a power management integrated circuit (PMIC). The PMIC may provide optimized power for each of the modules described above and modules described below. The power module 15 may include a wireless power transmission/reception circuit electrically connected to the battery. The wireless power transmission/reception circuit may include a plurality of coil-shaped antenna radiators.

The electronic device ED may further include a built-in module 16 and an exterior module 17. The built-in module 16 may include a sensor module 16-1, an antenna module 16-2, and an audio output module 16-3. The exterior module 17 may include a camera module 17-1, a light module 17-2, and a communication module 17-3.

The sensor module 16-1 may detect an input by the user's body or an input by the pen/stylus among the first input modules 13-1 to generate an electric signal or another form of data value corresponding to the input. The sensor module 16-1 may include at least one of a fingerprint sensor 16-11, an input sensor 16-12, or a digitizer 16-13.

The fingerprint sensor 16-11 may generate a data value corresponding to the user's fingerprint. The fingerprint sensor 16-11 may include either an optical or capacitive fingerprint sensor.

The input sensor 16-12 may generate data values corresponding to coordinate information of the input by the user's body or input by the pen/stylus. The input sensor 16-12 may generate a data value based on a change in electrostatic capacitance due to the input. The input sensor 16-12 may detect an input by a passive pen/stylus or transmit and receive data of an active pen/stylus.

The input sensor 16-12 may also measure bio-signals such as a blood pressure, moisture, or body fat. For example, when the user touches a portion of the his/her body to the sensor layer or sensing panel and then does not move for a certain period of time, the input sensor 16-12 may detect a bio-signal based on the change in electric fields caused by the portion of his/her body to output information desired by the user to the display module 14.

The digitizer 16-13 may generate data values corresponding to coordinate information input by the pen/stylus. The digitizer 16-13 may generate a change in electromagnetic caused by the input as the data value. The digitizer 16-13 may detect an input by the passive pen/stylus or transmit and receive data of the active pen/stylus.

At least two or more of the fingerprint sensor 16-11, the input sensor 16-12, and the digitizer 16-13 may be implemented as the input sensing layer ISL (see FIG. 3) disposed on the display panel 14-1 through a continuous process. The fingerprint sensor 16-11, the input sensor 16-12, and the digitizer 16-13 may be disposed above the display panel 14-1, and any one of the fingerprint sensor 16-11, the input sensor 16-12, and the digitizer 16-13, for example, the digitizer 16-13, may be disposed below the display panel 14-1.

At least one or more of the fingerprint sensor 16-11, the input sensor 16-12, and the digitizer 16-13 may be provided to be integrated into one sensing panel through the same process. When integrated into one sensing panel, the sensing panel may be disposed between the display panel 14-1 and the window disposed above the display panel 14-1. According to an embodiment of the present inventive concept, the sensing panel may be disposed on the window, and the position of the sensing panel is not necessarily particularly limited thereto.

At least one of the fingerprint sensor 16-11, the input sensor 16-12, or the digitizer 16-13 may be embedded into the display panel 14-1. For example, at least one of the fingerprint sensor 16-11, the input sensor 16-12, or the digitizer 16-13 may be provided simultaneously through a process of forming elements (e.g., the light emitting element, the transistor, etc.) included in the display panel 14-1.

In addition, the sensor module 16-1 may generate an electrical signal or data value corresponding to an internal or external state of the electronic device ED. The sensor module 16-1 may further include, for example, a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 16-2 may include one or more antennas for transmitting signals or power to the outside or receiving signals or power from the outside. According to an embodiment of the present inventive concept, the communication module 17-3 may transmit a signal to the external electronic device OD or receive a signal from the external electronic device OD through the antenna suitable for the communication method. The antenna pattern of the antenna module 16-2 may be integrated into one component of the display module 14 (e.g., display panel 14-1) or the input sensor 16-12.

The audio output module 16-3 may be a device for outputting audio signals to the outside of the electronic device ED and may include, for example, a speaker used for general purposes such as multimedia playback or recording playback and a receiver used exclusively for telephone reception. According to an embodiment of the present inventive concept, the receiver may be provided integrally with or separately from the speaker. A sound output pattern of the sound output module 16-3 may be integrated into the display module 14.

The camera module 17-1 may photograph still images and moving images. According to an embodiment of the present inventive concept, the camera module 17-1 may include one or more lenses, image sensors, or image signal processors. The camera module 17-1 may further include an infrared camera capable of measuring presence or absence of the user, the user's position, the user's line of sight, etc.

The light module 17-2 may provide light. The light module 17-2 may include a light emitting diode or a xenon lamp. The light module 17-2 may operate in conjunction with the camera module 17-1 or operate independently.

The communication module 17-3 may support establishment of a wired or wireless communication channel between the electronic device ED and the external electronic device OD, and performance of communication through the established communication channel. The communication module 17-3 may include one or both of a wireless communication module such as a cellular communication module, a short-range wireless communication module, or a global navigation satellite system (GNSS) communication module, and a wired communication module such as a local area network (LAN) communication module, or a power line communication module. The communication module 17-3 may communicate with the external electronic device OD through a short-range communication network such as Bluetooth, WiFi direct, or infrared data association (IrDA), or a long-range communication network such as a cellular network, the Internet, or a computer network (e.g., a LAN or WAN). The various types of communication modules 17-3 described above may be implemented as one chip or as separate chips.

The input module 13, the sensor module 16-1, the camera module 17-1, etc. may control the operation of the display module 14 in conjunction with the processor 11.

The processor 11 may output a command or data to the display module 14, the audio output module 16-3, the camera module 17-1, or the light module 17-2 based on the input data received from the input module 13. For example, the processor 11 may generate image data in response to the input data applied through the mouse or the active pen/stylus, etc., and output the image data to the display module 14, or generate command data in response to the input data and output the image data to the camera module 17-1 or the light module 17-2. When no input data is received from the input module 13 for a certain period of time, the processor 11 may reduce the power consumed by the electronic device ED by switching the operation mode of the electronic device ED to a low power mode or sleep mode.

The processor 11 may output a command or data to the display module 14, the audio output module 16-3, the camera module 17-1, or the light module 17-2 based on the sensing data received from the sensor module 16-1. For example, the processor 11 may compare authentication data authorized by the fingerprint sensor 16-11 with authentication data stored in the memory 12 and then execute an application based on the comparison result. The processor 11 may execute a command or output corresponding image data to the display module 14 based on the sensing data detected by the input sensor 16-12 or the digitizer 16-13. When a temperature sensor is included in the sensor module 16-1, the processor 11 may receive temperature data on a temperature measured from the sensor module 16-1 and further perform brightness correction, etc. on the image data based on the temperature data.

The processor 11 may receive measurement data on the presence or absence of the user, the user's position, the user's line of sight, etc. from the camera module 17-1. The processor 11 may further perform brightness correction, etc. on the image data based on the measurement data. For example, the processor 11 that determines the presence or absence of the user through the input from the camera module 17-1 may output image data of which brightness has been corrected through the data conversion circuit 11-22 or the gamma correction circuit 11-23 to the display module 14.

Some of the above components may be connected to each other through the communication method between peripheral devices, such as a bus, a general purpose input/output (GPIO), a serial peripheral interface (SPI), a mobile industry processor interface (MIPI), or an ultra path interconnect (UPI) link, to exchange signals (e.g., commands or data) with each other. The processor 11 may communicate with the display module 14 through a mutually agreed upon interface. For example, the processor 11 may use any of the above-described communication methods and is not necessarily limited to the above-described communication methods.

FIG. 3 is an exploded perspective view of the electronic device ED of FIG. 1.

Referring to FIG. 3, the electronic device ED may include a display module DM and a housing HU. The display module DM may include a window WN and a display unit DS. The display module DM according to an embodiment of the present inventive concept may further include a circuit board electrically connected to the display unit DS and transmitting a driving signal.

A window WN may be disposed on the display unit DS. The window WN may be coupled to the display unit DS through a process such as lamination. The window WN may cover the display unit DS and may protect the display unit DS from external impact and scratches.

The window WN may include an optically transparent insulating material. For example, the window WN may include a base film including glass or a synthetic resin. The window WN may have a single-layer or multi-layer structure. For example, the multi-layered window WN may include synthetic resin films bonded through an adhesive or may include a glass film and a synthetic resin film bonded through an adhesive. The window WN may further include functional layers such as an anti-fingerprint layer, a phase control layer, and a hard coating layer, which are disposed on the base film.

The window WN may include a transmission area, and the transmission area of the window WN may correspond to the display area of the electronic device ED described above. The transmission area of the window WN may transmit an image output from the display unit DS, and the user may view the image from the outside of the electronic device ED. The transmission area of the window WN may include a main transmission surface TA-M and first to fourth side transmission surfaces TA-S1, TA-S2, TA-S3, and TA-S4.

The main transmission area TA-M may correspond to the main display area DA-M. The main transmission surface TA-M may include a plane substantially parallel to the plane defined by the first direction DRI and the second direction DR2, which is perpendicular to the first direction DR1.

Each of the first to fourth side transmission surfaces TA-S1, TA-S2, TA-S3, and TA-S4 may have a curvature and may be bent from the main transmission surface TA-M. Each of the first to fourth side penetration surfaces TA-S1, TA-S2, TA-S3, and TA-S4 may include a curved surface extending from the main transmission surface TA-M. The first to fourth side transmission surfaces TA-S1, TA-S2, TA-S3, and TA-S4 may correspond to the first to fourth sub-display areas DA-S1, DA-S2, DA-D3, and DA-S4 described above, respectively.

The main transmission surface TA-M and the first to fourth side transmission surfaces TA-S1, TA-S2, TA-S3, and TA-S4 may be disposed adjacent to each other and may implement a continuous transmission area. The first to fourth side transmission surfaces TA-S1, TA-S2, TA-S3, and TA-S4 may be connected to each other and may surround the main penetration surface TA-M. Each of the first side transmission surface TA-S1 and the third side transmission surface TA-S3 may extend along the first direction DR1, and each of the second side transmission surface TA-S2 and the fourth side transmission surface TA-S4 may extend along the second direction DR2.

The display unit DS may be disposed below the window WN and may be attached to the window WN. The display unit DS may display an image based on an electrical signal. In some embodiments of the present inventive concept, the display unit DS may transmit and receive information about the external input. The display unit DS may include an active area AA-DA and a peripheral area AA-NDA adjacent to the active area AA-DA.

The active area AA-DA may be activated by an electrical signal and may be an area that displays an image. According to an embodiment of the present inventive concept, the active area AA-DA may be an area on which an image is displayed, and also, an external input is detected. However, an area on which the image is displayed and an area on which the external input is detected within the active area AA-DA may be separated from each other and are not necessarily limited to any one embodiment.

The display element DS may include pixels PX disposed on the active area AA-DA. The arrangement of the pixels PX within the active area AA-DA may be designed in various manners and is not necessarily limited to any one embodiment. Each of the pixels PX may include a pixel driving circuit including a light emitting element, transistors (e.g., a switching transistor and a driving transistor), and at least one capacitor, and may be connected to the light emitting element. The pixels PX may output light in response to an electrical signal applied to each pixel PX and may display an image through the active area AA-DA.

The active area AA-DA may overlap the transmission area of the window WN. Thus, the image output from the active area AA-DA may be viewed by the user through the transmission area of the window WN.

The peripheral area AA-NDA may be disposed adjacent to the active area AA-DA. For example, the transmission area AA-NDA may surround an active area AA-DA. However, this embodiment is not necessarily limited thereto, and the peripheral area AA-NDA may be defined in various shapes. A driving circuit, a driving line, such as a pad, for transmitting a signal that drive the active area AA-DA may be disposed on the peripheral area AA-NDA.

The display unit DS may include a flat part FA and at least one bent part. FIG. 3 illustrates an example in which the display unit DS includes first to fourth bent parts BA-S1, BA-S2, BA-S3, and BA-S4.

The flat part FA may include a plane substantially parallel to the plane defined by the first direction DR1 and the second direction DR2. The flat part FA may overlap the main transmission surface TA-M. A front surface of the flat part FA may be provided as the active area AA-DA. However, this embodiment is not necessarily limited thereto, and a portion of the flat part FA may be provided as the peripheral area AA-NDA.

Each of the first to fourth bent parts BA-S1, BA-S2, BA-S3, and BA-S4 of the display unit DS may extend from the flat part FA and then may be bent. Each of the first to fourth bent parts BA-S1, BA-S2, BA-S3, and BA-S4 may extend from the flat part FA and include a curved surface having a curvature. The first to fourth bent parts BA-S1, BA-S2, BA-S3, and BA-S4 may overlap the first to fourth side transmission surfaces TA-S1, TA-S2, TA-S3 of the window WN, and TA-S4, respectively.

The flat part FA and the first to fourth bent parts BA-S1, BA-S2, BA-S3, and BA-S4 may be disposed adjacent to each other to implement a continuous active area AA-DA. A portion of each of the first to fourth bent parts BA-S1, BA-S2, BA-S3, and BA-S4 may be provided as a portion of the active area AA-DA. For example, the display unit DS may output an image through at least some of the first to fourth bent parts BA-S1, BA-S2, BA-S3, and BA-S4. According to an embodiment of the present inventive concept, at least some of the first to fourth bent parts BA-S1, BA-S2, BA-S3, and BA-S4 may be provided as the peripheral areas AA-NDA. For example, a portion of the first to fourth bent parts BA-S1, BA-S2, BA-S3, and BA-S4 may correspond to the active area AA-DA, and a portion of the first to fourth bent parts BA-S1, BA-S2, BA-S3, and BA-S4 may correspond to the peripheral areas AA-NDA.

The first to fourth bending sections BA-S1, BA-S2, BA-S3, and BA-S4 may be connected to each other and may surround the flat part FA. Each of the first bent part BA-S1 and the third bent part BA-S3 may extend from the flat part FA in a direction parallel to the first direction DR1. Each of the first bent part BA-S1 and the third bent part BA-S3 may extend along the first direction DRI and include a curved surface that is bent about a bending axis parallel to the first direction DR1. Each of the second bent part BA-S2 and the fourth bent part BA-S4 may extend from the flat part FA in a direction parallel to the second direction DR2. Each of the second bent part BA-S2 and the fourth bent part BA-S4 may extend along the second direction DR2 and may include a surface that is bent about a bending axis parallel to the second direction DR2.

In a process of attaching the display unit DS to the window WN, the flat part FA of the display unit DS may be attached to the main transmission surface TA-M of the window WN. The first to fourth bent parts BA-S1, BA-S2, BA-S3, and BA-S4 of the display unit DS may be attached to the first to fourth side transmission surfaces TA-S1, TA-S2, TA-S3, and TA-S4 of the window WN, respectively.

The first bent part BA-S1 corresponding to a lower end of the display unit DS may further include a protruding portion PA provided as the peripheral area AA-NDA. The protruding portion PA may be bent toward a rear surface of the display unit DS corresponding to the flat part FA about the bending axis parallel to the first direction DR1. For example, the protruding portion PA may overlap the flat part FA on a plane. The protruding portion PA may be an area to which the circuit board of the display module DM is connected, or on which a driving chip is mounted. However, this embodiment is not necessarily limited thereto, and the protruding portion PA may be omitted.

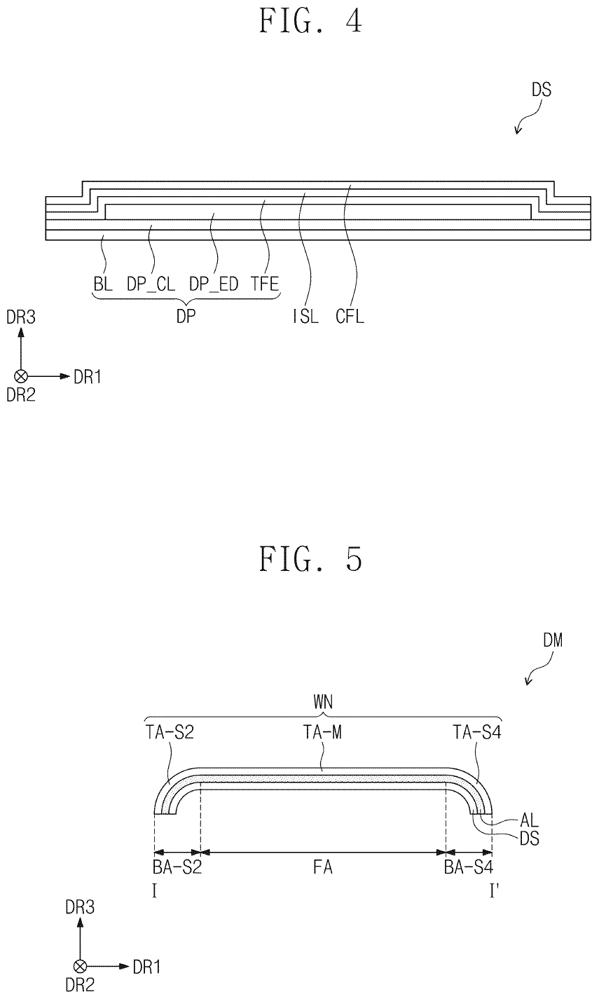

FIG. 4 is a cross-sectional view of the display unit DS according to an embodiment of the inventive concept.

Referring to FIG. 4, the display unit DS may include a display panel DP. The display panel DP according to an embodiment of the present inventive concept may be an emissive display panel, but is not necessarily limited thereto. For example, the display panel DP may be an organic light emitting display panel, an inorganic light emitting display panel, or a quantum dot light emitting display panel. The light emitting layer of the organic light emitting display panel may include an organic light emitting material, and the light emitting layer of the inorganic light emitting display panel may include an inorganic light emitting material. A light emitting layer of the quantum dot light emitting display panel may include a quantum dot, a quantum rod, and the like. Hereinafter, the display panel DP is described as an organic light emitting display panel.

The display panel DP may include a base layer BL, a circuit layer DP_CL, a display element layer DP_ED, and an encapsulation layer TFE.

The base layer BL may provide a base surface on which the circuit layer DP_CL is disposed. The base layer BL may be a rigid substrate or a flexible substrate capable of being bent, folded, or rolled. For example, the base layer BL may be a glass substrate, a metal substrate, or a polymer substrate.

The base layer BL may have a multilayer structure. For example, the base layer BL may include synthetic resin layers and at least one inorganic layer disposed between the synthetic resin layers. Each of the synthetic resin layers of the base layer BL may include at least one of an acrylic-based resin, a methacrylic-based resin, a polyisoprene, a vinyl-based resin, an epoxy-based resin, a urethane-based resin, a cellulose-based resin, a siloxane-based resin, a polyamide-based resin, a perylene-based resin, or a polyimide-based resin. However, the material of the base layer BL is not necessarily limited to the above-described examples.

The circuit layer DP_CL may be disposed on the base layer BL. The circuit layer DP_CL may include an insulating pattern, a semiconductor pattern, and a conductive pattern that form a pixel driving circuit, a driving line, and a pad of the pixel PX (see FIG. 3). In a step of manufacturing the display panel DP, the insulating layer, the semiconductor layer, and the conductive layer may be disposed on the base layer BL through coating or deposition, etc., and then, the insulating layer, the semiconductor layer, and the conductive layer may be patterned through photolithography several times to provide the circuit layer DP_CL.

The display element layer DP_ED may be disposed on the circuit layer DP_CL. The display element layer DP_ED may include light emitting elements constituting the pixels PX (see FIG. 3). The light emitting elements may be electrically connected to the pixel driving circuit of the circuit layer DP_CL. The light emitting elements may include an organic light emitting element, an inorganic light emitting element, a micro LED, a nano LED, or the like, but are not necessarily limited thereto as long as an amount of light is controlled according to an electrical signal.

The encapsulation layer TFE may be disposed on the display element layer DP_ED and may seal the display element layer DP_ED. The encapsulation layer TFE may include at least one thin film for improving optical efficiency of the display element layer DP_ED or protecting the display element layer DP_ED. For example, the encapsulation layer TFE may include at least one of an inorganic film or an organic film. The inorganic film of the encapsulation layer TFE may protect the display element layer DP_ED from moisture/oxygen. The organic film of the encapsulation layer TFE may protect the display element layer DP_ED from foreign substances such as dust particles.

The inorganic film of the encapsulation layer TFE may include at least one of aluminum oxide, titanium oxide, silicon oxide, silicon nitride, silicon oxynitride, zirconium oxide, or hafnium oxide. The organic film of the encapsulation layer TFE may include an acrylic-based resin. However, the material of the encapsulation layer TFE is not necessarily limited to the above examples.

The display unit DS may further include an input sensing layer ISL and an anti-reflection layer CFL. The input sensing layer ISL and the anti-reflection layer CFL may be disposed on the display panel DP along the third direction DR3.

The input sensing layer ISL may be disposed on the display panel DP. The input sensing layer ISL may be disposed directly on the display panel DP. In this embodiment of the present inventive concept, that “the input sensing layer ISL is directly disposed on the display panel DP” means that the input sensing layer ISL is provided on the display panel DP through a continuous process so that the input sensing layer ISL and the display panel DP are coupled without a separate adhesive layer. However, this embodiment is not necessarily limited thereto, and the input sensing layer ISL may be coupled to the display panel DP through an adhesive layer.

The input sensing layer ISL may acquire coordinate information of an external input applied from outside the electronic device ED (see FIG. 1). The external input may include various types of inputs such as force, a pressure, a temperature, or light. For example, the external input may include an input such as a user's hand or an electromagnetic pen/stylus that is in contact with the electronic device ED (see FIG. 1) or an input such as hovering applied in proximity to the electronic device ED (see FIG. 1).

The input sensing layer ISL may be driven in various manners and may detect the external input applied from the outside of the electronic device ED (see FIG. 1). For example, the input sensing layer ISL may operate by a capacitive method, a resistive method, an infrared method, an acoustic wave method, or a pressure method, but is not necessarily limited thereto as long as the input sensing layer ISL detects the external input.

The anti-reflection layer CFL may be disposed on the input sensing layer ISL. For example, the anti-reflection layer CFL may be disposed directly on the input sensing layer ISL. The anti-reflection layer CFL may be disposed on the base surface provided by the input sensing layer ISL. However, this embodiment is not necessarily limited thereto, and the anti-reflection layer CFL may be coupled to the input sensing layer ISL through the adhesive layer. In addition, although the input sensing layer ISL is illustrated as being disposed below the anti-reflection layer CFL, the laminated order of the input sensing layer ISL and the anti-reflection layer CFL is not necessarily limited as being illustrated.

The anti-reflection layer CFL may reduce reflectance of external light that is incident from the upper portion of the electronic device ED (see FIG. 1). The anti-reflection layer CFL may include various materials that reduce the reflectance of the external light.

The anti-reflection layer CFL according to an embodiment of the present inventive concept may include a retarder and a polarizer. The retarder may include a N2 retarder (e.g., a half-wave plate) and/or a N/4 retarder (e.g., a quarter-wave plate). Each of the retarder and polarizer may be provided into a film type or liquid crystal coating type. The film type polarizer may include a stretchable synthetic resin film, and the liquid crystal coating type polarizer may include liquid crystals arranged in a predetermined array. This embodiment of the present inventive concept is not necessarily limited thereto, and the retarder and the polarizer may be implemented as a single polarizing film. The anti-reflection layer CFL may further include a protective film disposed above or below the polarizing film.

The anti-reflection layer CFL according to an embodiment of the present inventive concept may include a destructive interference structure. For example, the destructive interference structure may include a first reflective layer and a second reflective layer, which are disposed on different layers. First reflected light reflected from the first reflective layer and second reflected light reflected from the second reflective layer may destructively interfere with each other, and thus, the anti-reflection layer CFL may reduce the reflectance of the external light.

The anti-reflection layer CFL according to an embodiment of the present inventive concept may include color filters. The color filters may be arranged corresponding to the arrangement and emission colors of the pixels PX (see FIG. 3) included in the display panel DP. The anti-reflection layer CFL may filter external light that is incident onto the upper portion of the electronic device ED (see FIG. 1), transforming it into a color that corresponds to the emission color of each pixel PX (see FIG. 3). The anti-reflection layer CFL may further include a black matrix disposed adjacent to the color filters.

The display unit DS may further include a lower member disposed below the display panel DP. The lower member may include at least one layer that protects the display panel DP. For example, the lower member may include a light blocking layer, a heat dissipation layer, or a cushioning layer.

The light blocking layer may prevent the components disposed on the rear surface of the display panel DP from being visible from the outside of the display unit DS. The light blocking layer may include a light blocking material and may prevent the reflected light from being transmitted to the outside of the display unit DS. For example, the light blocking layer may include a binder and pigment particles such as carbon black dispersed therein.

The heat dissipation layer may dissipate heat generated from the elements disposed below the display panel DP and may protect the display panel DP. The heat dissipation layer may include materials having heat dissipation properties such as stainless steel, graphite, copper (Cu), or aluminum (Al). In addition to elements having the heat dissipation properties, the heat dissipation layer may include elements having electromagnetic wave shielding or electromagnetic wave absorption properties and may prevent noise from being generated in the display panel DP.

The cushion layer may absorb an external impact applied to the rear surface of the display panel DP. The cushion layer may include an elastic material. For example, the cushion layer may include synthetic resin foam having a porous structure. The plurality of pores dispersed in the cushion layer may absorb the external impact and may improve impact resistance of the display unit DS.

FIG. 5 is a cross-sectional view of the display module DM according to an embodiment of the inventive concept. FIG. 5 is a cross-sectional view of the display device DD, which is taken along line I-I′ of FIG. 3.

The display module DM may include the window WN and the display unit DS, and an adhesive layer AL disposed between the window WN and the display unit DS.

The adhesive layer AL may be configured to bond the window WN to the display unit DS. The adhesive layer AL may be disposed directly on the display unit DS. A top surface of the adhesive layer AL may be in contact with a bottom surface of the window WN, and a bottom surface of the adhesive layer AL may be in contact with a top surface of the display unit DS.

The adhesive layer AL may include a transparent adhesive such as a pressure sensitive adhesive film, an optically clear adhesive film, or an optically clear resin.

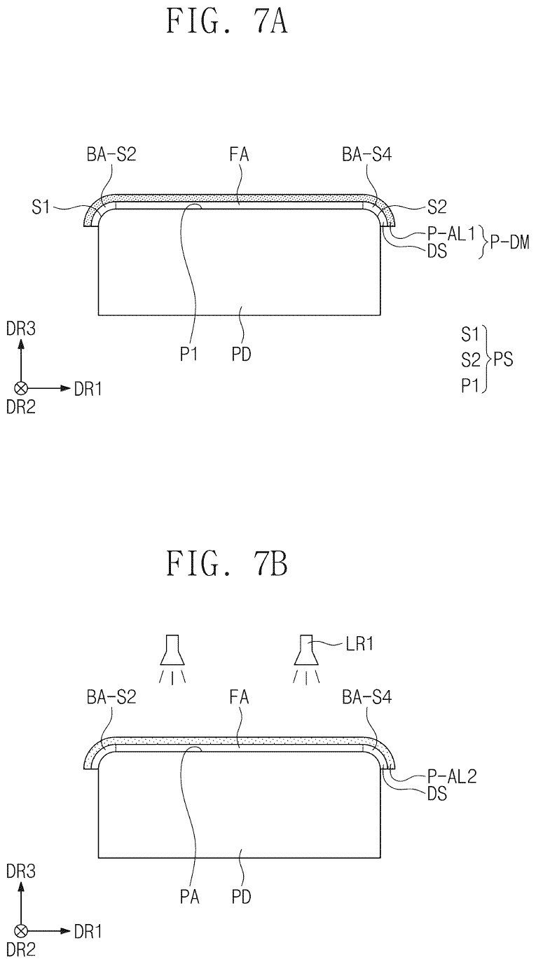

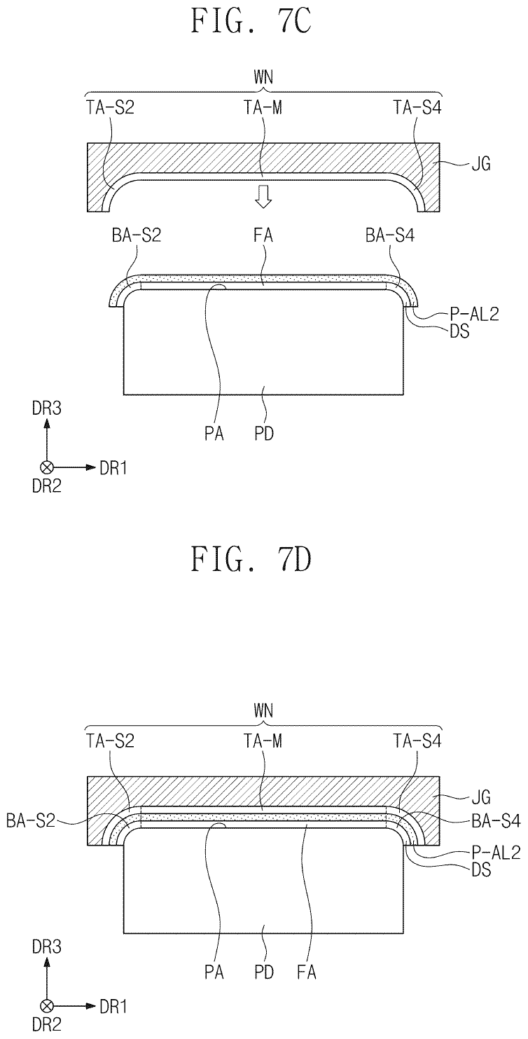

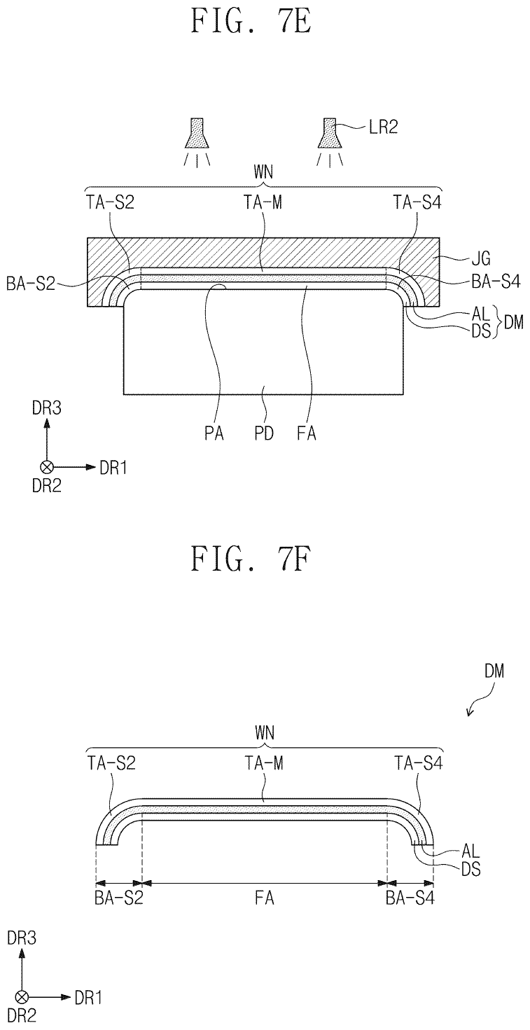

The adhesive layer AL may include a first adhesive material. The first adhesive material may have first adhesive reversibility with respect to the first light LR1 (see FIG. 7B). For example, the first adhesive material may have properties that change when exposed to the first light LR1. In this specification of the present inventive concept, the adhesive reversibility with respect to light may mean a property in which the adhesive strength is changed depending on whether or not it is exposed to light. A wavelength of the first light LR1 may range from about 100 nm and to about 400 nm. The first light LR1 may mean ultraviolet light. The first adhesive reversibility with respect to the first light LR1 may mean a property in which the adhesive strength is changed depending on whether or not it is exposed to the first light LR1. For example, the first adhesive material may have a property in which the adhesive strength is weakened when exposed to the first light LR1.

The first adhesive material may have second adhesive reversibility with respect to the second light LR2. A wavelength of the second light LR2 may be different from the wavelength of the first light LR1. The wavelength of the second light LR2 may range from about 400 nm to about 700 nm. The second light LR2 may mean visible light. The second adhesive reversibility with respect to the second light LR2 may mean a property in which the adhesive strength is changed depending on whether or not it is exposed the second light LR2. For example, the first adhesive material may have a property in which the adhesive strength is enhanced when exposed to the second light LR2.

The first adhesive material may include a curable resin. The first adhesive material may include a thermosetting resin or a photocurable resin. For example, the first adhesive material may include a photocurable resin. The first adhesive material may include a visible light-curable resin.

The first adhesive material may have a cured or softened state depending on the exposure of the first light LR1 or the second light LR2. The first adhesive material may be reversibly switched between the cured state and the softened state depending on a wavelength range of light to which the first adhesive material is exposed. Thus, the adhesion state of the first adhesive material may be reversibly controlled by the wavelength range of the light to which the first adhesive material is exposed. For example, the first adhesive material may have a softened state when it is exposed to light with a relatively low wavelength range and the first adhesive material may have a cured state when it is exposed to light with a relatively high wavelength range. For example, the cured state may hold the window WN and the display unit DS more firmly than the softened state, which would have weakened bonding state. When the first adhesive material is exposed to the first light LR1, the first adhesive material may be in the softened state. When the first adhesive material is exposed to the second light LR2 having a relatively high wavelength range compared to the first light LR1, the first adhesive material may be in the cured state. The states of the first adhesive material may be switched by a photoreversible Diels-Alder reaction, a photoreversible isomerization reaction, or a photoreversible dimerization reaction. However, this embodiment is not necessarily limited thereto.

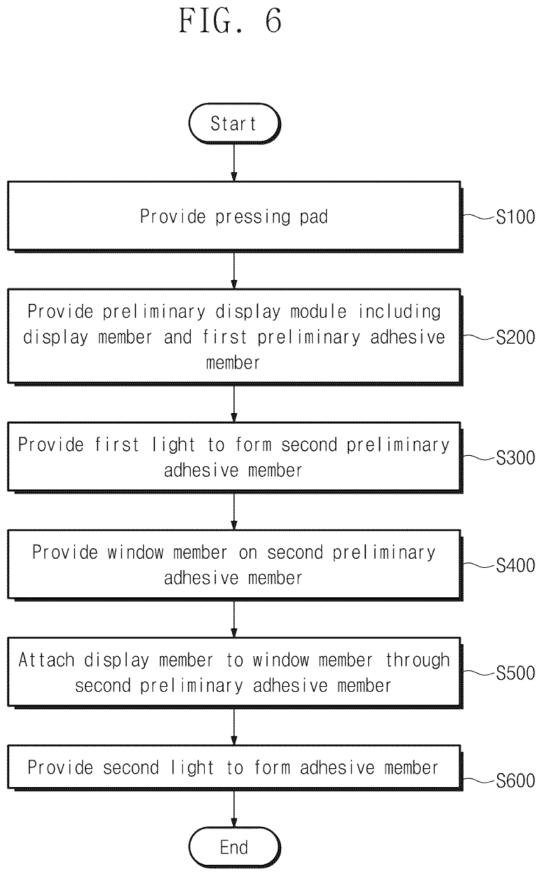

FIG. 6 is a flowchart illustrating a method for manufacturing a display module according to an embodiment of the present inventive concept. FIGS. 7A to 7F are cross-sectional views illustrating some steps in the method for manufacturing the display module according to an embodiment of the present inventive concept. A method for manufacturing a display module DM according to an embodiment of the present inventive concept may be a method for manufacturing the display module DM according to the foregoing embodiments, which are described with reference to FIGS. 1 to 5. Hereinafter, in description of the method for manufacturing the display module according to an embodiment with reference to FIG. 6 and FIGS. 7A to 7F the same reference numerals will be given to the same components as those described above. To the extent that an element has not been described in detail, it may be assumed that the element is at least similar to corresponding elements that have been described in FIGS. 1 to 5.

Referring to FIG. 6, the method for manufacturing the display module DM according to an embodiment of the present inventive concept may include a step (S100) of providing a pressing pad, a step (S200) of providing a preliminary display module DM including a display panel and a first preliminary adhesive layer P-AL1 (see FIG. 7A), a step (S300) of forming a second preliminary adhesive layer P-AL2 (see FIG. 7A) by providing first light LR1, a step (S400) of providing a window on the second preliminary adhesive layer P-AL2, a step (S500) of attaching the display panel to the window through the second preliminary adhesive layer P-AL2 member, and a step (S600) of forming the adhesive layer AL by providing second light LR2.

FIG. 7A schematically illustrates the step (S100) of providing the pressing pad and the step (S200) of providing a preliminary display module including the display panel and the first preliminary adhesive in the method for manufacturing the display module according to an embodiment of the present inventive concept. FIG. 7B schematically illustrates the step (S300) of forming the second preliminary adhesive layer P-ALI by providing the first light in the method for manufacturing the display module according to an embodiment of the present inventive concept. FIG. 7C schematically illustrates the step (S400) of providing the window WN on the second preliminary adhesive layer P-ALI in the method for manufacturing the display module DM according to an embodiment of the present inventive concept. FIG. 7D schematically illustrates the step (S500) of attaching the display unit DS to the window WN using the second preliminary adhesive layer P-AL2 in the method for manufacturing the display module DM according to an embodiment of the present inventive concept. FIG. 7E schematically illustrates the step (S600) of forming the adhesive layer AL by providing the second light LR2 in the method for manufacturing the display module DM according to an embodiment of the present inventive concept. FIG. 7F schematically illustrates the display module DM manufactured through the steps described above.

Referring to FIGS. 6 and 7A, the method for manufacturing the display module DM according to an embodiment of the present inventive concept may include the step (S100) of providing the pressing pad PD. The method for manufacturing the display module DM according to an embodiment of the present inventive concept may include the step (S200) of providing the preliminary display module P-DM on the pressing pad PD.

The pressing pad PD may include a material of which a shape is easily deformed by a pressure. For example, the pressing pad PD may include an elastic material such as silicone.

The pressing pad PD may include a pressing surface. The pressing surface of the pressing pad PD may include a first surface P1 and first and second side surfaces S1 and S2 that are bent from the first surface P1. Each of the first side surface S1 and the second side surface S2 may include a curved surface extending from the first surface P1. The first surface P1 of the pressing pad PD may overlap a flat part FA of the display unit DS and may support the flat part FA. For example, the first surface P1 of the pressing pad PD may be disposed below the flat part FA of the display unit DS. The first side surface S1 of the pressing pad PD may overlap a second bent part BA-S2 of the display unit DS, and the second side surface S2 may overlap a fourth bent part BA-S4 of the display unit DS.

The preliminary display module P-DM may include a display unit DS and a first preliminary adhesive layer P-AL1 disposed on the display unit DS. The preliminary display module P-DM may be provided on the pressing pad PD. The second bent part BA-S2 and the fourth bent part BA-S4 of the display unit DS may be bent corresponding to a shape of the pressing pad PD. The first preliminary adhesive layer P-ALI disposed on the display unit DS may have a shape corresponding to a shape of the display unit DS. However, this embodiment is not necessarily limited thereto, and a guide film may be further provided on the pressing pad PD to implement the bent shape of the preliminary display module P-DM.

Referring to FIGS. 6 and 7B, the method for manufacturing the display module DM according to an embodiment of the present inventive concept may include the step (S300) of providing the first light LRI on the preliminary display module P-DM to form a second preliminary adhesive layer P-AL2.

The second preliminary adhesive layer P-AL2 may be formed by providing the first light LR1 to the first preliminary adhesive layer P-AL1. A wavelength of the first light LR 1 may be range from about 100 nm to about 400 nm. The first light LR1 may be ultraviolet light. The second preliminary adhesive layer P-AL2 may be in the softened state as the second preliminary adhesive layer P-AL2 is formed by being exposed to the first light LR1.

Referring to FIG. 6, FIG. 7B and FIG. 7C, the method for manufacturing the display module DM according to an embodiment of the present inventive concept may include the step (S400) of providing the window WN on the second preliminary adhesive layer P-AL2 and the step (S500) of attaching the display unit DS to the window WN through the second preliminary adhesive layer P-AL2.

The step (S400) of providing the window WN on the second preliminary adhesive layer P-AL2 may include a step of providing a jig JG, which holds the window WN during an assembly process. For example, the window WN may be placed onto the second adhesive layer P-AL2 while positioned on the jig JG. For example, the window WN may be fixed within an accommodation groove formed within the jig JG. The window WN may have a shape corresponding to a shape of the accommodation groove of the jig JG.

The step (S400) of providing the window WN on the second preliminary adhesive layer P-AL2 may further include, after the step of providing the jig JG on which the window WN is disposed on the second preliminary adhesive layer P-AL2, a step of moving the jig JG, in which the window WN is accommodated, toward the second preliminary adhesive layer P-AL2.

The display unit DS and the window WN may be attached through the second preliminary adhesive layer P-AL2. Since the second preliminary adhesive layer P-AL2 is in the softened state after being exposed to the first light LR1, the second preliminary adhesive layer P-AL2 may have relatively low adhesive strength. Thus, the display unit DS and the window WN may be weakly bonded to each other.

A flat part FA of the display unit DS may be attached to a main transmission surface TA-M of the window WN. The second bent part BA-S2 of the display unit DS may be attached to a second side transmission surface TA-S2 of the window WN, and a fourth bent part BA-S4 of the display unit DS may be attached to a fourth side transmission surface TA-S4 of the window WN. The flat part FA of the display unit DS and the main transmission surface TA-M of the window WN may be flat, but, in comparison, each of the second and fourth bent parts BA-S2 and BA-S4 of the display unit DS and the second and fourth side transmission surfaces TA-S2 and TA-S4 of the window WN may have a predetermined curvature. As the second preliminary adhesive layer P-AL2 is in the softened state, the second preliminary adhesive layer P-AL2 may be uniformly applied and may be adhered to a top surface of each of the second and fourth bent part BA-S2 and BA-S4 of the display unit DS and a bottom surface of each of the second and fourth side transmission surface TA-S2 and TA-S4 of the window WN. Thus, first attachment strength between the flat part FA of the display unit DS and the main transmission surface TA-M of the window WN and second attachment strength between the second and fourth bent parts BA-S2 and BA-S4 of the display unit DS and the second and fourth side transmission surfaces TA-S2 and TA-S4 of the window WN may be substantially the same. In this specification, the “substantially the same” may include not only a case in which the thicknesses and attachment strengths of components are physically completely the same, but also a case in which there is a difference by an error range that occurs during the process in spite of the same design. Since the second preliminary adhesive layer P-AL2 is in the softened state, bonding reliability between the display unit DS and the window WN may be improved, and a limitation in which bubbles occur between the second and fourth bent part BA-S2 and BA-S4 of the display unit DS and the second and fourth side transmission surfaces TA-S2 and TA-S4 of the window WN may be solved.

Referring to FIGS. 6 and 7E, the method for manufacturing the display module DM according to an embodiment of the present inventive concept may include the step (S600) of forming the adhesive layer AL by providing the second light LR2 to the second preliminary adhesive layer P-AL2.

Referring to FIGS. 7D and 7E, the adhesive layer AL may be formed by providing the second light LR2 to the second preliminary adhesive layer P-AL2. A wavelength of the second light LR2 may range from about 400 nm to about 700 nm. The second light LR2 may be visible light. The adhesive layer AL may be in the cured state as the adhesive layer AL is formed by being exposed to the second light LR2. Since the adhesive layer AL is in the cured state, the adhesive strength may be relatively high, and thus, the display unit DS and the window WN may be strongly bonded. Thus, the first adhesive strength of the second preliminary adhesive layer P-AL2 may be less than the second adhesive strength of the adhesive layer AL. The adhesion strength of the second preliminary adhesive layer P-AL2 to the display unit DS may be less than the adhesion strength of the adhesive layer AL to the display unit DS. The adhesion strength of the second preliminary adhesive layer P-AL2 to the window WN may be less than the adhesion strength of the adhesive layer AL to the window WN.

The second preliminary adhesive layer P-AL2 may include a first material, and the adhesive layer AL may include a second material formed by reversibly curing the first material using the second light LR2. The first material may be in the softened state, and the second material may be in the cured state. The first material may have a relatively low contact angle compared to that of the second material, and the first material may have a relatively small modulus compared to that of the second material. Thus, the second preliminary adhesive layer P-AL2 including the first material may be uniformly applied to and may contact with each of the second and fourth bent parts BA-S2 and BA-S4 of the display unit DS, each of which has a predetermined curvature, and the second and fourth side transmission surfaces TA-S2 and TA-S4 of the window WN.

Referring to FIGS. 7E and 7F, the method for manufacturing the display module DM according to an embodiment of the present inventive concept may include, after the step of forming the adhesive layer AL, a step of removing the pressing pad PD from the display unit DS and a step of removing the jig JG from the window WN. The display unit DS, the window WN, and the adhesive layer AL that couples the display unit DS to the window WM may constitute the display module DM.

The method for manufacturing the display module DM according to an embodiment of the present inventive concept may include the step of attaching the display unit DS to the window WN by the second preliminary adhesive layer P-AL2 in the softened state and then photocuring the second preliminary adhesive layer P-AL2, thereby being spread more evenly across the surfaces and improving the bonding reliability between the display unit DS and the window WN. The flat part FA of the display unit DS and the main transmission surface TA-M of the window WN may be flat, but, in comparison, each of the first to fourth bent parts BA-S1, BA-S2, BA-S3, and BA-S4 of the display unit DS and the first to fourth side transmission surfaces TA-S1, TA-S2, TA-S3, and TA-S4 of the window WN may have a predetermined curvature. Thus, the first to fourth bent parts BA-S1, BA-S2, BA-S3, and BA-S4 of the display unit DS may be difficult to be sufficiently bonded to the window WSN compared to the flat part FA. However, since the second preliminary adhesive layer P-AL2 is in the softened state, the second preliminary adhesive layer P-AL2 may be uniformly applied and adhered to each of the second and fourth bent parts BA-S2 and BA-S4 of the display unit DS, each of which has a predetermined curvature, and the second and fourth side transmission surfaces TA-S2 and TA-S4 of the window WN. For example, even if the second preliminary adhesive layer P-AL2 is in contact with the bottom surface of the window WN in the step of moving the window WN toward the display unit DS, the second preliminary adhesive layer P-AL2 may have low adhesiveness because of the softened state, and thus, a phenomenon in which the second adhesive layer P-AL2 is concentrated only at a specific position might not occur. Thus, the adhesive reliability of the second adhesive layer P-AL2 may be improved. In addition, the second preliminary adhesive layer P-AL2 may have adhesive reversibility with respect to the second light LR2. For example, as the second preliminary adhesive layer P-AL2 is cured by visible light, the display unit DS and the window WN may be bonded to each other with high strength. When manufactured by the method for manufacturing the display module DM according to an embodiment of the present inventive concept, the limitation in which the bubbles occur between the first to fourth bent parts BA-S1, BA-S2, BA-S3, and BA-S4 of the display unit DS and the first to fourth side transmission surfaces TA-S1, TA-S2, TA-S3, and TA-S4 of the window WN may be solved, and the bonding reliability between the display unit DS and the window WN may be improved.

The display module DM according to the embodiment of the present inventive concept may include the adhesive layer AL including the first adhesive material that improves the bonding reliability between the display unit DS and the window WN.

The electronic device ED including the display module DM according to the embodiment of the present inventive concept may include the adhesive layer AL that improves the device reliability.

The method for manufacturing the display module DM according to the embodiment of the present inventive concept may include the step of allowing the display unit DS and the window WN to adhere to each other by the second preliminary adhesive layer P-AL2 and then curing the second preliminary adhesive layer P-AL2, thereby providing the display module DM having the improved bonding reliability between the display unit DS and the window WN.

It will be apparent to those skilled in the art that various modifications and variations can be made in the present inventive concept. Thus, it is intended that the present disclosure covers the modifications and variations of this invention provided they come within the scope of the appended claims and their equivalents.

What is claimed is:

1. A display module, comprising:
a display unit comprising a flat part and a bent part that extends from the flat part;
a window disposed on the display unit; and
an adhesive layer disposed between the display unit and the window,
wherein the adhesive layer comprises a first adhesive material with a first degree of adhesiveness that is dependent upon exposure to a first light.

2. The display module of claim 1, wherein a wavelength of the first light ranges from 100 nm to 400 nm.

3. The display module of claim 1, wherein the first adhesive material has second degree of adhesiveness that is dependent upon exposure to a second light having a wavelength different from a wavelength of the first light.

4. The display module of claim 3, wherein the wavelength of the second light ranges from 400 nm to 700 nm.

5. The display module of claim 3, wherein the first adhesive material has a cured state or a softened state depending on exposure to the first light or the second light.

6. The display module of claim 1, wherein the first adhesive material comprises a curable resin.

7. The display module of claim 1, wherein the adhesive layer comprises a pressure sensitive adhesive film, an optically clear adhesive film, or an optically clear resin.

8. The display module of claim 1, wherein the flat part comprises a first side extending along a first direction, and
wherein the bent part comprises a first bent part that extends from the first side.

9. The display module of claim 8, wherein the flat part comprises a second side extending along the first direction and facing the first side in a second direction intersecting the first direction, and
wherein the bent part further comprises a second bent part that extends from the second side.

10. The display module of claim 9, wherein the flat part comprises a third side and a fourth side, which extend along the second direction and face each other in the first direction, and
wherein the bent part comprises a third bent part and a fourth bent part, which extend from the third side and the fourth side, respectively.

11. The display module of claim 1, wherein the display unit comprises:
a base layer;
a circuit layer disposed on the base layer;
a display element layer disposed on the circuit layer; and
an encapsulation layer that seals the display element layer.

12. The display module of claim 11, wherein the display unit further comprises at least one of an input sensing layer or an anti-reflection layer, which is disposed on the encapsulation layer.

13. An electronic device, comprising:
a processor;
a memory having stored application programs for execution by the processor;
a display device, comprising:
a display unit comprising a flat part and a bent part that extends from the flat part;
a window disposed on the display unit;
an adhesive layer disposed between the display unit and the window; and
a housing coupled to the window and accommodating the display unit,
wherein the adhesive layer comprises a first adhesive material having a first degree of adhesiveness that is dependent upon exposure to a first light; and
a user interface configured to sense user input via touch or cursor a cursor selection of an icon presented on the display unit, wherein the processor is caused to execute one or more stored application programs upon receipt of the user input.

14. A method for manufacturing a display module, the method comprising:
providing a pressing pad comprising a curved pressing surface;
disposing a preliminary display module comprising a display unit and a first preliminary adhesive layer, which is disposed on the display unit, on the pressing pad;
exposing the preliminary display module to a first light to form a second preliminary adhesive layer;
disposing a window on the second preliminary adhesive layer;
attaching the display unit to the window through the second preliminary adhesive layer; and
exposing the window to a second light to form an adhesive layer,
wherein a first adhesive strength of the second preliminary adhesive layer is less than a second adhesive strength of the adhesive layer.

15. The method of claim 14, wherein the display unit comprises a flat part and a bent part that extends from the flat part.

16. The method of claim 15, wherein in the attaching of the display unit to the window, a first attachment strength between the flat part and the window is substantially the same as a second attachment strength between the bent part and the window.

17. The method of claim 14, wherein a wavelength of the first light ranges from 100 nm to 400 nm, and
wherein a wavelength of the second light ranges from 400 nm to 700 nm.

18. The method of claim 14, wherein the second preliminary adhesive layer comprises a first material, and
wherein the adhesive layer comprises a second material formed by curing the first material using the second light.

19. The method of claim 18, wherein the first material has a relatively low contact angle compared to the second material.

20. The method of claim 18, wherein the first material has a relatively low clastic modulus compared to the second material.
